(19) United States
(12) Patent Application Publication
(10) Pub. No.: US 2023/0008851 A1
(43) Pub. Date: Jan. 12, 2023

(54) METHOD FOR IDENTIFYING LATCH-UP STRUCTURE

(71) Applicant: CHANGXIN MEMORY TECHNOLOGIES, INC., Hefei City (CN)

(72) Inventor: Qian XU, Hefei (CN)

(21) Appl. No.: 17/709,721

(22) Filed: Mar. 31, 2022

Related U.S. Application Data
(63) Continuation of application No. PCT/CN2021/122663, filed on Oct. 8, 2021.

(30) Foreign Application Priority Data
Jul. 8, 2021 (CN) 202110773732.4

(51) Int. Cl. H01L 27/02

(52) U.S. Cl. CPC H01L 27/0207; H01L 27/0262

(57) ABSTRACT

A method for identifying a latch-up structure includes the following operations. In a chip layout, a first P-type heavily doped region connected to a ground pad and located in a P-type substrate is found, and a first N-type heavily doped region connected to a power pad and located in an N-well is found. A second N-type heavily doped region adjacent to the first P-type heavily doped region and located in the P-type substrate is found. A second P-type heavily doped region adjacent to the first N-type heavily doped region and located in the N-well is found, the N-well is located on the P-type substrate. An area that is formed by the first P-type heavily doped region, the first N-type heavily doped region, the second P-type heavily doped region, the second N-type heavily doped region, the N-well, and the P-type substrate is identified as the latch-up structure.

### CROSS-REFERENCE TO RELATED APPLICATION

This disclosure is a continuation of International Application No. PCT/CN2021/122663, filed on Oct. 8, 2021, which is filed based on and claims priority to Chinese patent application No. 202110773732.4, filed on Jul. 8, 2021 and entitled “METHOD FOR IDENTIFYING LATCH-UP STRUCTURE”. The entire contents of International Application No. PCT/CN2021/122663 and Chinese patent application No. 202110773732.4 are incorporated herein by reference in their entireties.

### BACKGROUND

Reliability becomes increasingly important for semiconductor products, and latch-up is an extremely important item in reliability of semiconductor products. In a designed integrated circuit product, there may be various latch-up paths, and particularly in circuits connected to power pads (Power PAD), it is important to effectively inspect these possible latch-up paths and inspect their safety with existing design rules.

### SUMMARY

The embodiments of the present disclosure relates to a method of an Electro-Static discharge (ESD) protection circuit of a semiconductor integrated circuit, and particularly provide a method for identifying a latch-up structure.

According to a first aspect of the embodiments of the present disclosure, a method for identifying a latch-up structure is provided. The method includes the following operations. In a chip layout, a first P-type heavily doped region connected to a ground pad and located in a P-type substrate is found, and a first N-type heavily doped region connected to a power pad and located in an N-well is found.

A second N-type heavily doped region adjacent to the first P-type heavily doped region and located in the P-type substrate is found.

A second P-type heavily doped region adjacent to the first N-type heavily doped region and located in the N-well is found, the N-well is located on the P-type substrate.

An area that is formed by the first P-type heavily doped region, the first N-type heavily doped region, the second P-type heavily doped region, the second N-type heavily doped region, the N-well, and the P-type substrate is identified as the latch-up structure.

According to a second aspect of the embodiments of the present disclosure, a method for identifying a latch-up structure is provided, the method may include the following operations.

In a chip layout, a first P-type heavily doped region connected to a ground pad and located in a P-type substrate is found, and a first N-type heavily doped region connected to a power pad and located in a second N-well is found.

A second N-type heavily doped region adjacent to the first P-type heavily doped region and located in a first N-well is found.

A second P-type heavily doped region adjacent to the first N-type heavily doped region and located in the second N-well is found, both the first N-well and the second N-well are located on the P-type substrate.

An area that is formed by the first P-type heavily doped region, the first N-type heavily doped region, the second P-type heavily doped region, the second N-type heavily doped region, the first N-well, the second N-well, and the P-type substrate is identified as the latch-up structure.

According to a third aspect of the embodiments of the present disclosure, a method for identifying a latch-up structure is provided. The method includes the following operations.

In a chip layout, a first P-type heavily doped region connected to a ground pad and located in a P-type substrate is found, and a first N-type heavily doped region connected to a power pad and located in a second N-well is found.

A second N-type heavily doped region adjacent to the first P-type heavily doped region and located in a deep N-well is found.

A second P-type heavily doped region adjacent to the first N-type heavily doped region and located in the second N-well is found, the deep N-well is located in a first N-well, both the first N-well and the second N-well are located on the P-type substrate.

An area that is formed by the first P-type heavily doped region, the first N-type heavily doped region, the second P-type heavily doped region, the second N-type heavily doped region, the deep N-well, the first N-well, the second N-well, and the P-type substrate is identified as the latch-up structure.

### BRIEF DESCRIPTION OF THE DRAWINGS

FIG. 1A is a schematic flowchart of a method for identifying a latch-up structure provided in an embodiment of the present disclosure.

FIG. 1B is a top view of a latch-up structure provided in an embodiment of the present disclosure.

FIG. 1C is a sectional view of a latch-up structure provided in an embodiment of the present disclosure.

FIG. 2A is a schematic flowchart of a method for identifying a latch-up structure provided in an embodiment of the present disclosure.

FIG. 2B is a top view of a latch-up structure provided in an embodiment of the present disclosure.

FIG. 2C is a sectional view of a latch-up structure provided in an embodiment of the present disclosure.

FIG. 3A is a schematic flowchart of a method for identifying a latch-up structure provided in an embodiment of the present disclosure.

FIG. 3B is a top view of a latch-up structure provided in an embodiment of the present disclosure.

FIG. 3C is a sectional view of a latch-up structure provided in an embodiment of the present disclosure.

FIG. 4A is a schematic flowchart of a method for identifying a latch-up structure provided in an embodiment of the present disclosure.

FIG. 4B is a top view of a latch-up structure provided in an embodiment of the present disclosure.

FIG. 4C is a sectional view of a latch-up structure provided in an embodiment of the present disclosure.

FIG. 5A is a schematic flowchart of a method for identifying a latch-up structure provided in an embodiment of the present disclosure.

FIG. 5B is a top view of a latch-up structure provided in an embodiment of the present disclosure.

FIG. 5C is a sectional view of a latch-up structure provided in an embodiment of the present disclosure.

FIG. 6A is a schematic flowchart of a method for identifying a latch-up structure provided in an embodiment of the present disclosure.

FIG. 6B is a top view of a latch-up structure provided in an embodiment of the present disclosure.

FIG. 6C is a sectional view of a latch-up structure provided in an embodiment of the present disclosure.

FIG. 7A is a schematic flowchart of a method for identifying a latch-up structure provided in an embodiment of the present disclosure.

FIG. 7B is a top view of a latch-up structure provided in an embodiment of the present disclosure.

FIG. 7C is a sectional view of a latch-up structure provided in an embodiment of the present disclosure.

### REFERENCE NUMERALS

11, 21, 31, 41, 51, 61, 71—First P-type heavily doped regions
12, 22, 32, 42, 52, 62, 72—First N-type heavily doped regions
13, 23, 33, 43, 53, 63, 73—Second N-type heavily doped regions
14, 24, 34, 44, 54, 64, 74—Second P-type heavily doped regions
15, 25, 35, 45, 55, 65, 75—P-type substrates
16, 48, 58—N-wells
46, 56, 66, 76—P-wells
36, 47, 57, 67—Deep N-wells
77—First deep N-well
78—Second deep N-well
26, 37, 68, 79—First N-wells
27, 38, 69, 80—Second N-wells

### DETAILED DESCRIPTION

Exemplary implementations disclosed in the present disclosure will be described in more detail below with reference to the accompanying drawings. Although exemplary implementations of the present disclosure are shown in the accompanying drawings, it should be understood that the present disclosure may be implemented in various forms and should not be limited by the specific embodiments described herein. On the contrary, these implementations are provided in order to enable a more thorough understanding of the present disclosure and to fully convey the scope of the present disclosure to those skilled in the art.

In the following description, numerous specific details are given in order to provide a more thorough understanding of the present disclosure. However, it would be apparent to those skilled in the art that the present disclosure may be implemented without one or more of these details. In other examples, some technical features known in the art are not described in order to avoid confusion with the present disclosure. That is, not all features of the actual embodiments are described herein, and well-known functions and structures are not described in detail.

In the accompanying drawings, the dimensions of the layers, regions, elements and their relative dimensions may be exaggerated for clarity. The same reference numerals indicate the same elements throughout.

It should be understood that when an element or layer is referred to as being “on . . . ”, “adjacent to . . . ”, and “connected to . . . ” or “coupled to . . . ” other elements or layers, it may be directly on, adjacent to, connected to, or coupled to other elements or layers, or there may be intervening elements or layers. Conversely, when an element is referred to as being “directly on . . . ”, “directly adjacent to . . . ”, “directly connected to . . . ” or “directly coupled to . . . ” other elements or layers, there is no intervening element or layer. It should be understood that although the terms first, second, third and the like may be used to describe various elements, components, regions, layers and/or portions, these elements, components, regions, layers and/or portions should not be limited by these terms. These terms are used merely to distinguish one element, component, region, layer or portion from another element, component, region, layer or portion. Thus, without departing from the teachings of the present disclosure, a first element, component, region, layer or portion discussed below may be represented as a second element, component, region, layer or portion. And when the second element, component, region, layer or portion is discussed, it does not indicate that the first element, component, region, layer or portion is necessarily present in the present disclosure necessarily.

Spatial relationship terms such as “under . . . ”, “below . . . ”, “below”, “underneath . . . ”, “on . . . ”, “above” may be used herein for ease of description to describe the relationship of one element or feature shown in the figure to other elements or features. It should be understood that, in addition to the orientation shown in the drawings, spatial relationship terms are intended to encompass different orientations of devices in use and operation. For example, if the device in the drawings is turned over, then an element or feature described as “below other elements”, “underneath other elements”, “under other elements” will be oriented “above” other element or feature. Thus, the exemplary terms “under . . . ”, “below . . . ” may encompass both top and bottom orientations. The device may be additionally oriented (rotated 90 degrees or at other orientations) and the spatial descriptors used herein are interpreted accordingly.

The term used herein is only for a purpose of describing specific embodiments and is not intended as a limitation of the present disclosure. When used herein, the singular form “a”, “one” and “said/the” are also intended to include the plural form unless the context clearly indicates otherwise. It shall also be understood that the terms “composition” and/or “inclusion”, when used in this specification, determine the presence of the features, integers, steps, operations, elements and/or components, but the presence or addition of one or more other features, integers, steps, operations, elements, components and/or groups is not precluded. As used herein, the term “and/or” includes any and all combinations of the items listed herein. For example, “A and/or B” may have three meanings: A exists alone, A and B exist at the same time and B exists alone.

In order to fully understand the present disclosure, detailed steps and detailed structures will be proposed in the following description to illustrate the technical solutions of the present disclosure. Preferred embodiments of the present disclosure are described as follows in detail. However, other implementations in addition to these detailed descriptions may also be included in the present disclosure.

The identification and inspection of a parasitic latch-up path in current integrated circuits can ensure that an integrated circuit products do not fail due to latch-up, thus ensuring the reliability of the product. However, at present, there is generally no set of reliable, effective and comprehensive method for identifying and inspecting a parasitic latch-up path, which is a major challenge for prevention of latch-up.

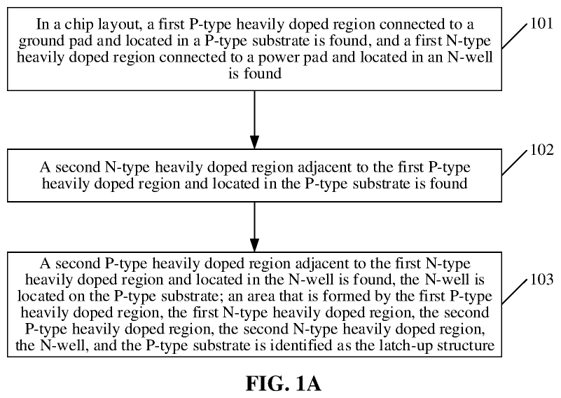

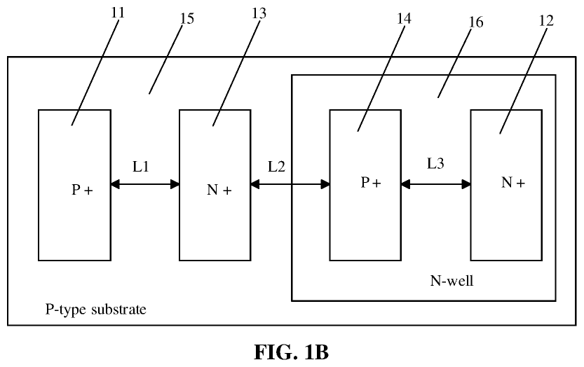

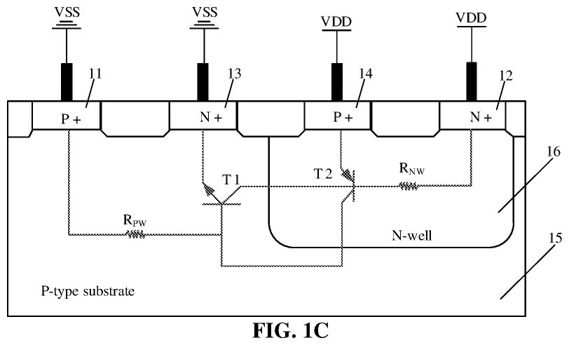

The method for identifying a latch-up structure provided by the present disclosure will be described in detail below through specific embodiments. FIGS. 1A to 7C illustrate a total of seven methods for identifying a latch-up structure. For different latch-up structures, the positions of a first N-type heavily doped region, a first P-type heavily doped region, a second N-type heavily doped region and a second P-type heavily doped region are arranged to be different. It should be noted that in FIGS. 1A to 7C, the P-type heavily doped regions are abbreviated as P+, the N-type heavily doped region are abbreviated as N+, a ground pad is abbreviated as VSS, and a power pad is abbreviated as VDD.

FIG. 1A is a schematic flowchart of a method for identifying a latch-up structure according to an embodiment of the present disclosure. As illustrated, the method includes the following operations.

In 101, in a chip layout, a first P-type heavily doped region connected to a ground pad and located in a P-type substrate is found, and a first N-type heavily doped region connected to a power pad and located in an N-well is found.

In 102, a second N-type heavily doped region adjacent to the first P-type heavily doped region and located in the P-type substrate is found.

In 103, a second P-type heavily doped region adjacent to the first N-type heavily doped region and located in the N-well is found, the N-well is located on the P-type substrate. An area that is formed by the first P-type heavily doped region, the first N-type heavily doped region, the second P-type heavily doped region, the second N-type heavily doped region, the N-well, and the P-type substrate is identified as the latch-up structure.

The method for identifying a latch-up structure provided in the embodiments of the present disclosure is further described in detail below with reference to specific embodiments.

FIG. 1B is a top view of a latch-up structure provided in an embodiment of the present disclosure. FIG. 1C is a sectional view of a latch-up structure provided in an embodiment of the present disclosure.

Before the operation in 101 is performed, the ground pad and power pad are found, the power pad includes pad such as VDD PAD, VDDQ PAD and the like.

Next, as illustrated in FIG. 1C, the operation in 101 is performed. In a chip layout, a first P-type heavily doped region 11 connected to a ground pad and located in a P-type substrate 15 is found, and a first N-type heavily doped region 12 connected to a power pad and located in a N-well 16 is found.

In one embodiment, the operation that the first P-type heavily doped region 11 connected to the ground pad and located in the P-type substrate 15 is found, includes the following operation. The first P-type heavily doped region 11 directly or indirectly connected to the ground pad and located in the P-type substrate 15 is found.

The operation that the first N-type heavily doped region 12 connected to the power pad and located in the N-well 16 is found, includes the following operation. The first N-type heavily doped region 12 directly or indirectly connected to the power supply pad and located in the N-well 16 is found.

Here, the operation that the first P-type heavily doped region 11 directly connected to the ground pad is found and the operation that the first N-type heavily doped region 12 directly connected to the power pad is found, mean that the ground pad is directly connected to the first P-type heavily doped region 11 and the power pad is directly connected to the first N-type heavily doped region 12 without other devices.

The operation that the first P-type heavily doped region 11 indirectly connected to the ground pad is found and the operation that the first N-type heavily doped region 12 indirectly connected to the power pad is found, mean that the ground pad may be connected to the first P-type heavily doped region 11 and the power pad may be connected to the first N-type heavily doped region 12, respectively, by means of a high current conducting path. Specifically, for example, it may be connected by a resistor having low resistance, a switching device or a diode. More specifically, the ground pad may be connected to the first P-type heavily doped region 11 by means of a forward diode, and the power pad may be connected to the first N-type heavily doped region 12 by means of a backward diode.

Next, the operation in 102 is performed. A second N-type heavily doped region 13 adjacent to the first P-type heavily doped region 11 and located in the P-type substrate 15 is found.

In this embodiment, the second N-type heavily doped region 13 is connected to the ground pad.

The second N-type heavily doped region 13 may be directly or indirectly connected to the ground pad. The indirect connection includes a connection by means of a high current conducting path. Specifically, for example, it may be connected by a resistor having low resistance, a switching device or a diode.

Next, the operation in 103 is performed. A second P-type heavily doped region 14 adjacent to the first N-type heavily doped region 12 and located in the N-well 16 is found. The N-well 16 is located on the P-type substrate 15. An area that is formed by the first P-type heavily doped region 11, the first N-type heavily doped region 12, the second P-type heavily doped region 14, the second N-type heavily doped region 13, the N-well 16, and the P-type substrate 15 is identified as the latch-up structure.

In this embodiment, the second P-type heavily doped region 14 is connected to the power pad.

The second P-type heavily doped region 14 may be directly or indirectly connected to the power pad. The indirect connection includes a connection by means of a high current conducting path. Specifically, for example, it may be connected by a resistor having low resistance, a switching device or a diode.

In one embodiment, the operation that the second N-type heavily doped region 13 adjacent to the first P-type heavily doped region 11 and located in the P-type substrate 15 is found that by taking the first P-type heavily doped region 11 as a center and taking a preset distance as a radius, the second N-type heavily doped region 13 is identified, a distance of which to the first P-type heavily doped region 11 is less than the preset distance; and/or, the operation that the second P-type heavily doped region 14 adjacent to the first N-type heavily doped region 12 and located in the N-well 16 is found, includes that by taking the first N-type heavily doped region 12 as a center and taking a preset distance as a radius, the second P-type heavily doped region 14 is identified, a distance of which to the first N-type heavily doped region 12 is less than the preset distance.

In one embodiment, as illustrates in FIG. 1B, there is a first distance L1 between the first P-type heavily doped region 11 and the second N-type heavily doped region 13, a second distance L2 between the second N-type heavily doped region 13 and the second P-type heavily doped region 14, and a third distance L3 between the second P-type heavily doped region 14 and the first N-type heavily doped region 12.

The operation that by taking the first P-type heavily doped region 11 as a center and taking a preset distance as a radius, the second N-type heavily doped region 13 is identified, a distance of which to the first P-type heavily doped region 11 is less than the preset distance, specifically includes: the first distance is less than the preset distance.

The operation that, by taking the first N-type heavily doped region 12 as a center and taking a preset distance as a radius, the second P-type heavily doped region 14 is identified, a distance of which to the first N-type heavily doped region 12 is less than the preset distance, specifically includes: the third distance is less than the preset distance.

Furthermore, as illustrated in FIG. 1C, the N-well 16, the P-type substrate 15, and the second N-type heavily doped region 13 constitute a first parasitic NPN transistor T1. The second P-type heavily doped region 14, the N-well 16, and the P-type substrate 15 constitute a first parasitic PNP transistor T2.

The P-type substrate 15 has a first parasitic resistor R_{PW}, a first end of which is connected to the first P-type heavily doped region 11, and a second end of which is connected to a base electrode of the first parasitic NPN transistor T1.

The N-well 16 has a second parasitic resistor R_{NW}, a first end of which is connected to the first N-type heavily doped region 12, and a second end of which is connected to a base electrode of the first parasitic PNP transistor T2.

The following describes a principle of generating a latch-up effect in the latch-up structure. Specifically, T2 is a vertical PNP transistor, the base electrode is an N-well, a gain from the base electrode to a collector electrode may reach tens of times, T1 is a side NPN transistor, the base electrode is a P-type substrate, a gain from the base electrode to the collector electrode may reach tens of times, R_{NW} is a parasitic resistor of the N-well, and Rₚw is a parasitic resistor of the P-type substrate.

The above four elements T1, T2, R_{NW} and R_{PW} constitute a silicon controlled circuit. When there is no external interference and no trigger is caused, the two transistors are in a turned-off state, a collector electrode current is formed by a reverse leakage current of C-B, and a current gain is extremely small, so a latch-up effect will not occur at this time. When a collector electrode current of one of the transistors suddenly increases to a certain value due to external interference, a feedback is sent to the other transistor, so that the two transistors are triggered to be turned on (generally, PNP is easier to be triggered), and a low-impedance path is formed between the power pad VDD and the ground pad VSS. Then, even if the external interference disappears, because a positive feedback is formed between the two triodes, there will still be a leakage current between the power pad VDD and the ground pad VSS, that is, a locked state. This results in a latch-up effect.

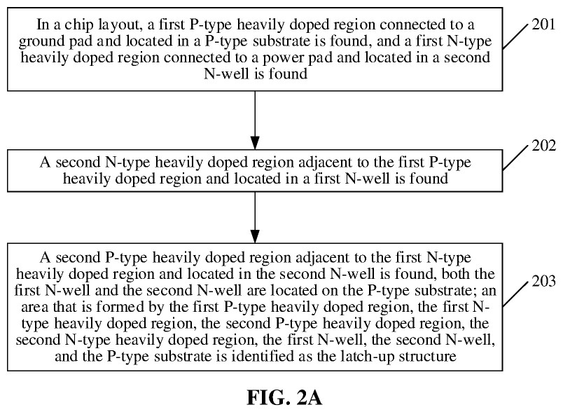

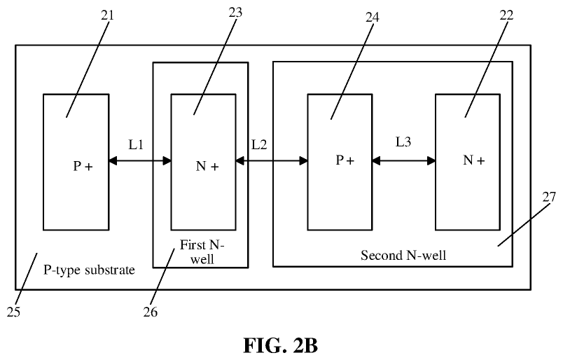

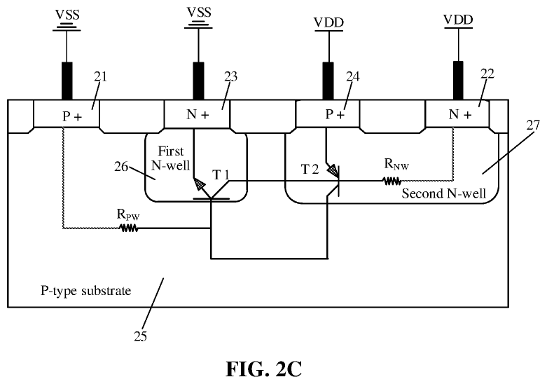

FIG. 2A is a schematic flowchart of a method for identifying a latch-up structure provided in an embodiment of the present disclosure. As illustrated, the method includes the following operations:

In 201, in a chip layout, a first P-type heavily doped region connected to a ground pad and located in a P-type substrate is found, and a first N-type heavily doped region connected to a power pad and located in a second N-well is found.

In 202, a second N-type heavily doped region adjacent to the first P-type heavily doped region and located in a first N-well is found.

In 203, a second P-type heavily doped region adjacent to the first N-type heavily doped region and located in the second N-well is found. Both the first N-well and the second N-well are located on the P-type substrate. An area that is formed by the first P-type heavily doped region, the first N-type heavily doped region, the second P-type heavily doped region, the second N-type heavily doped region, the first N-well, the second N-well, and the P-type substrate is identified as the latch-up structure.

The method for identifying a latch-up structure provided in the embodiments of the present disclosure is further described in detail below with reference to specific embodiments.

FIG. 2B is a top view of a latch-up structure provided in an embodiment of the present disclosure. FIG. 2C is a sectional view of a latch-up structure provided in an embodiment of the present disclosure.

Before the operation in 201 is performed, the ground pad and power pad are found, the power pad includes pad such as VDD PAD, VDDQ PAD and the like.

Next, as illustrated in FIG. 2C, the operation in 201 is performed. In a chip layout, a first P-type heavily doped region 21 connected to a ground pad and located in a P-type substrate 25 is found, and a first N-type heavily doped region 22 connected to a power pad and located in the second N-well 27 is found.

In one embodiment, the operation that the first P-type heavily doped region 21 connected to the ground pad and located in the P-type substrate 25 is found, includes the following operation. The first P-type heavily doped region 21 directly or indirectly connected to the ground pad and located in the P-type substrate 25 is found.

The operation that the first N-type heavily doped region 22 connected to the power pad and located in the second N-well 27 includes the following operation. The first N-type heavily doped region 22 directly or indirectly connected to the power supply pad and located in the second N-well 27 is found.

Here, the operation that the first P-type heavily doped region 21 directly connected to the ground pad is found, and the operation that the first N-type heavily doped region 22 directly connected to the power pad is found, mean that the ground pad is directly connected to the first P-type heavily doped region 21 and the power pad is directly connected to the first N-type heavily doped region 22 without other devices.

The operation that the first P-type heavily doped region 21 indirectly connected to the ground pad is found and the operation that the first N-type heavily doped region 22 indirectly connected to the power pad is found, mean that the ground pad may be connected to the first P-type heavily doped region 21 and the power pad may be connected to the first N-type heavily doped region 22, respectively, by means of a high current conducting path. Specifically, for example, it may be connected by a resistor having low resistance, a switching device or a diode. More specifically, the ground pad may be connected to the first P-type heavily doped region 21 by means of a forward diode, and the power pad may be connected to the first N-type heavily doped region 22 by means of a backward diode.

Next, the operation in 202 is performed. A second N-type heavily doped region 23 adjacent to the first P-type heavily doped region 21 and located in the first N-well 26 is found.

In this embodiment, the second N-type heavily doped region 23 is connected to the ground pad.

The second N-type heavily doped region 23 may be directly or indirectly connected to the ground pad. The indirect connection includes a connection by means of a high current conducting path. Specifically, for example, it may be connected by a resistor having low resistance, a switching device or a diode.

Next, the operation in 203 is performed. A second P-type heavily doped region 24 adjacent to the first N-type heavily doped region 22 and located in the second N-well 27 is found. Both the first N-well 26 and the second N-well 27 are located on the P-type substrate 25. An area that is formed by the first P-type heavily doped region 21, the first N-type heavily doped region 22, the second P-type heavily doped region 24, the second N-type heavily doped region 23, the first N-well 26, the second N-well 27 and the P-type substrate 25 is identified as the latch-up structure.

In this embodiment, the second P-type heavily doped region 24 is connected to the power pad.

The second P-type heavily doped region 24 may be directly or indirectly connected to the power pad. The indirect connection includes a connection by means of a high current conducting path. Specifically, for example, it may be connected by a resistor having low resistance, a switching device or a diode.

In one embodiment, the operation that the second N-type heavily doped region 23 adjacent to the first P-type heavily doped region 21 and located in the first N-well 26 is found, includes that by taking the first P-type heavily doped region 21 as a center and taking a preset distance as a radius, the second N-type heavily doped region 23 is identified, a distance of which to the first P-type heavily doped region 21 is less than the preset distance; and/or, the operation that the second P-type heavily doped region 24 adjacent to the first N-type heavily doped region 22 and located in the second N-well 27 is found, includes that by taking the first N-type heavily doped region 22 as a center and taking a preset distance as a radius, the second P-type heavily doped region 24 is identified, a distance of which to the first N-type heavily doped region 22 is less than the preset distance.

In one embodiment, as illustrates in FIG. 2B, there is a first distance L1 between the first P-type heavily doped region 21 and the second N-type heavily doped region 23, a second distance L2 between the second N-type heavily doped region 23 and the second P-type heavily doped region 24, and a third distance L3 between the second P-type heavily doped region 24 and the first N-type heavily doped region 22.

The operation that, by taking the first P-type heavily doped region 21 as a center and taking a preset distance as a radius, the second N-type heavily doped region 23 is identified, a distance of which to the first P-type heavily doped region 21 is less than the preset distance, specifically includes: the first distance is less than the preset distance.

The operation that, by taking the first N-type heavily doped region 22 as a center and taking a preset distance as a radius, the second P-type heavily doped region 24 is identified, a distance of which to the first N-type heavily doped region 22 is less than the preset distance is identified, specifically includes: the third distance is less than the preset distance.

Furthermore, as illustrated in FIG. 2C, the second N-well 27, the P-type substrate 25, and the second N-type heavily doped region 23 constitute a first parasitic NPN transistor T1. The second P-type heavily doped region 24, the second N-well 27, and the P-type substrate 25 constitute a first parasitic PNP transistor T2.

The P-type substrate 25 has a first parasitic resistor R_{PW}, a first end of which is connected to the first P-type heavily doped region 21, and a second end of which is connected to a base electrode of the first parasitic NPN transistor T1.

The second N-well 27 has a second parasitic resistor R_{NW}, a first end of which is connected to the first N-type heavily doped region 22, and a second end of which is connected to a base electrode of the first parasitic PNP transistor T2.

The following describes a principle of generating a latch-up effect in the latch-up structure. Specifically, T2 is a vertical PNP transistor, the base electrode is an N-well, a gain from the base electrode to a collector electrode may reach tens of times, T1 is a side NPN transistor, the base electrode is a P-type substrate, a gain from the base electrode to the collector electrode may reach tens of times, R_{NW} is a parasitic resistor of the N-well, and Rₚw is a parasitic resistor of the P-type substrate.

The above four elements T1, T2, R_{NW} and R_{PW} constitute a silicon controlled circuit. When there is no external interference and no trigger is caused, the two transistors are in a turned-off state, a collector electrode current is formed by a reverse leakage current of C-B, and a current gain is extremely small, so the latch-up effect will not occur at this time. When a collector electrode current of one of the transistors suddenly increases to a certain value due to external interference, a feedback is sent to the other transistor, so that the two transistors are triggered to be turned on (generally, the PNP is easier to be triggered), and a low-impedance path is formed between the power pad VDD and the ground pad VSS. Then, even if the external interference disappears, because a positive feedback is formed between the two triodes, there will still be a leakage current between the power pad VDD and the ground pad VSS, that is, a locked state. This results in a latch-up effect.

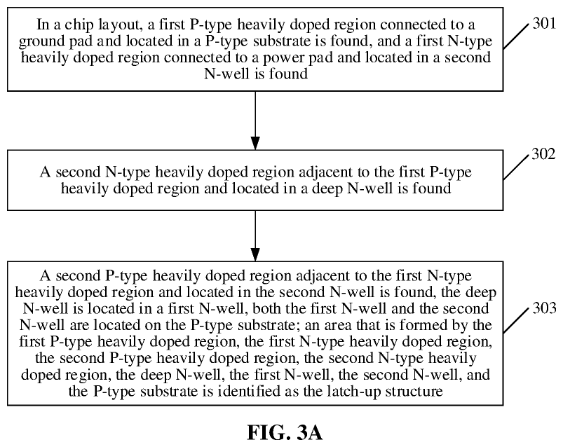

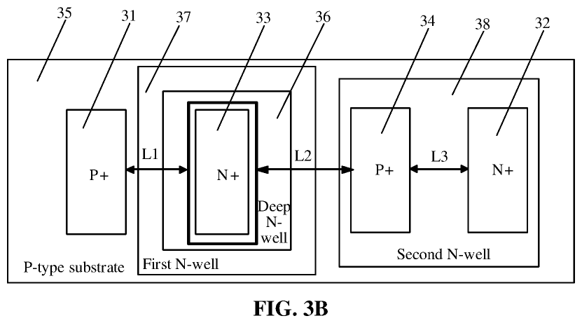

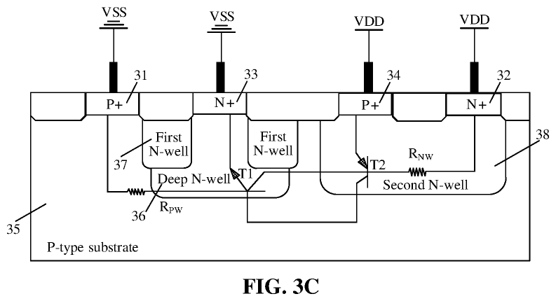

FIG. 3A is a schematic flowchart of a method for identifying a latch-up structure provided in an embodiment of the present disclosure. As illustrated, the method includes the following operations.

In 301, in a chip layout, a first P-type heavily doped region connected to a ground pad and located in a P-type substrate is found, and a first N-type heavily doped region connected to a power pad and located in a second N-well is found.

In 302, a second N-type heavily doped region adjacent to the first P-type heavily doped region and located in a deep N-well is found.

In 303, a second P-type heavily doped region adjacent to the first N-type heavily doped region and located in the second N-well is found. The deep N-well is located in a first N-well, both the first N-well and the second N-well are located on the P-type substrate. An area that is formed by the first P-type heavily doped region, the first N-type heavily doped region, the second P-type heavily doped region, the second N-type heavily doped region, the deep N-well, the first N-well, the second N-well, and the P-type substrate is identified as the latch-up structure.

The method for identifying a latch-up structure provided in the embodiments of the present disclosure is further described in detail below with reference to specific embodiments.

FIG. 3B is a top view of a latch-up structure provided in an embodiment of the present disclosure. FIG. 3C is a sectional view of a latch-up structure provided in an embodiment of the present disclosure.

Before the operation in 301 is performed, the ground pad and power pad are found, the power pad includes pad such as VDD PAD, VDDQ PAD and the like.

Next, as illustrated in FIG. 3C, the operation in 301 is performed. In the chip layout, a first P-type heavily doped region 31 connected to a ground pad and located in a P-type substrate 35 is found, and a first N-type heavily doped region 32 connected to a power pad and located in a second N-well 38 is found.

In one embodiment, the operation that the first P-type heavily doped region 31 connected to the ground pad and located in the P-type substrate 35 is found, includes the following operation. The first P-type heavily doped region 31 directly or indirectly connected to the ground pad and located in the P-type substrate 35 is found.

The operation that the first N-type heavily doped region 32 connected to the power pad and located in the second N-well 38 is found, includes the following operation. The first N-type heavily doped region 32 directly or indirectly connected to the power supply pad and located in the second N-well 38 is found.

Here, the operation that the first P-type heavily doped region 31 directly connected to the ground pad is found and the operation that the first N-type heavily doped region 32 directly connected to the power pad is found, mean that the ground pad is directly connected to the first P-type heavily doped region 31 and the power pad is directly connected to the first N-type heavily doped region 32 without other devices.

The operation that the first P-type heavily doped region 31 indirectly connected to the ground pad is found and the operation that the first N-type heavily doped region 32 indirectly connected to the power pad is found, mean that the ground pad may be connected to the first P-type heavily doped region 31 and the power pad may be connected to the first N-type heavily doped region 32, respectively, by means of a high current conducting path. Specifically, for example, it may be connected by a resistor having low resistance, a switching device or a diode. More specifically, the ground pad may be connected to the first P-type heavily doped region 31 by means of a forward diode, and the power pad may be connected to the first N-type heavily doped region 32 by means of a backward diode.

Next, the operation in 302 is performed. A second N-type heavily doped region 33 adjacent to the first P-type heavily doped region 31 and located in the deep N-well 36 is found.

In this embodiment, the second N-type heavily doped region 33 is connected to the ground pad.

The second N-type heavily doped region 33 may be directly or indirectly connected to the ground pad. The indirect connection includes a connection by means of a high current conducting path. Specifically, for example, it may be connected by a resistor having low resistance, a switching device or a diode.

Next, the operation in 303 is performed. A second P-type heavily doped region 34 adjacent to the first N-type heavily doped region 32 and located in the second N-well 38 is found. The deep N-well 36 is located in the first N-well 37, both the first N-well 37 and the second N-well 38 are located on the P-type substrate 35, An area that is formed by the first P-type heavily doped region 31, the first N-type heavily doped region 32, the second P-type heavily doped region 34, the second N-type heavily doped region 33, the deep N-well 36, the first N-well 37, the second N-well 38 and the P-type substrate 35 is identified as the latch-up structure.

In this embodiment, the second P-type heavily doped region 34 is connected to the power pad.

The second P-type heavily doped region 34 may be directly or indirectly connected to the power pad. The indirect connection includes a connection by means of a high current conducting path. Specifically, for example, it may be connected by a resistor having low resistance, a switching device or a diode.

In one embodiment, the operation that the second N-type heavily doped region 33 adjacent to the first P-type heavily doped region 31 and located in the deep N-well 36 is found, includes that by taking the first P-type heavily doped region 31 as a center and taking a preset distance as a radius, the second N-type heavily doped region 33 is identified, a distance of which to the first P-type heavily doped region 31 is less than the preset distance; and/or, the operation that the second P-type heavily doped region 34 adjacent to the first N-type heavily doped region 32 and located in the second N-well 38 is found, includes that by taking the first N-type heavily doped region 32 as a center and taking a preset distance as a radius, the second P-type heavily doped region 34 is identified, a distance of which to the first N-type heavily doped region 32 is less than the preset distance.

In one embodiment, as illustrates in FIG. 3B, there is a first distance L1 between the first P-type heavily doped region 31 and the second N-type heavily doped region 33, a second distance L2 between the second N-type heavily doped region 33 and the second P-type heavily doped region 34, and a third distance L3 between the second P-type heavily doped region 34 and the first N-type heavily doped region 32.

The operation that, by taking the first P-type heavily doped region 31 as a center and taking a preset distance as a radius, the second N-type heavily doped region 33 is identified, a distance of which to the first P-type heavily doped region 31 is less than the preset distance, specifically includes: the first distance is less than the preset distance.

The operation that, by taking the first N-type heavily doped region 32 as a center and taking a preset distance as a radius, the second P-type heavily doped region 34 is identified, a distance of which to the first N-type heavily doped region 32 is less than the preset distance, specifically includes: the third distance is less than the preset distance.

Furthermore, as illustrated in FIG. 3C, the second N-well 38, the P-type substrate 35, and the deep N-well 36 constitute a first parasitic NPN transistor T1. The second P-type heavily doped region 34, the second N-well 38, and the P-type substrate 35 constitute a first parasitic PNP transistor T2.

The P-type substrate 35 has a first parasitic resistor R_{PW}, a first end of which is connected to the first P-type heavily doped region 31, and a second end of which is connected to an emitter of the first parasitic NPN transistor T1.

The second N-well 38 has a second parasitic resistor R_{NW}, a first end of which is connected to the first N-type heavily doped region 32, and a second end of which is connected to a base electrode of the first parasitic PNP transistor T2.

The following describes a principle of generating a latch-up effect in the latch-up structure. Specifically, T2 is a vertical PNP transistor, the base electrode is an N-well, a gain from the base electrode to a collector electrode may reach tens of times, T1 is a side NPN transistor, the base electrode is a P-type substrate, a gain from the base electrode to the collector electrode may reach tens of times, R_{NW} is a parasitic resistor of the N-well, and Rₚw is a parasitic resistor of the P-type substrate.

The above four elements T1, T2, R_{NW} and R_{PW} constitute a silicon controlled circuit. When there is no external interference and no trigger is caused, the two transistors are in a turned-off state, a collector electrode current is formed by a reverse leakage current of C-B, and a current gain is extremely small, so the latch-up effect will not occur at this time. When a collector electrode current of one of the transistors suddenly increases to a certain value due to external interference, a feedback is sent to the other transistor, so that the two transistors are triggered to be turned on (generally, the PNP is easier to be triggered), and a low-impedance path is formed between the power pad VDD and the ground pad VSS. Then, even if the external interference disappears, because a positive feedback is formed between the two triodes, there will still be a leakage current between the power pad VDD and the ground pad VSS, that is, a locked state. This results in a latch-up effect.

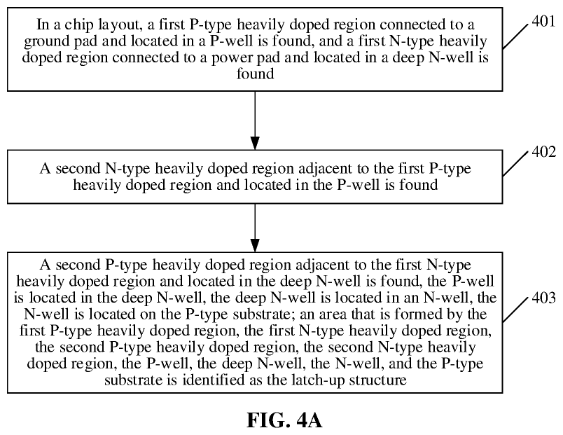

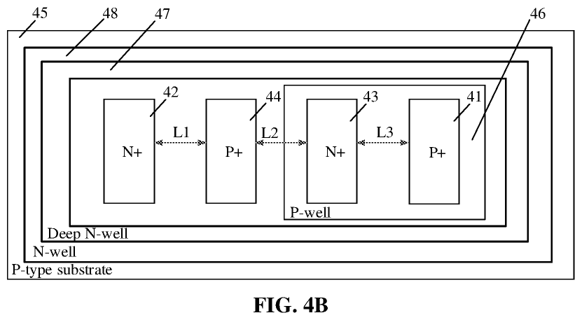

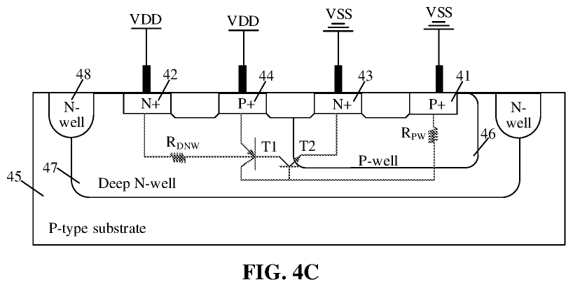

FIG. 4A is a schematic flowchart of a method for identifying a latch-up structure provided in an embodiment of the present disclosure. As illustrated, the method includes the following operations.

In 401, in a chip layout, a first P-type heavily doped region connected to a ground pad and located in a P-well is found, and a first N-type heavily doped region connected to a power pad and located in a deep N-well is found.

In 402, a second N-type heavily doped region adjacent to the first P-type heavily doped region and located in the P-well is found.

In 403, a second P-type heavily doped region adjacent to the first N-type heavily doped region and located in the deep N-well is found. The P-well is located in the deep N-well, the deep N-well is located in an N-well, and the N-well is located in a P-type substrate. An area that is formed by the first P-type heavily doped region, the first N-type heavily doped region, the second P-type heavily doped region, the second N-type heavily doped region, the P-well, the deep N-well, the N-well, and the P-type substrate is identified as the latch-up structure.

The method for identifying a latch-up structure provided in the embodiments of the present disclosure is further described in detail below with reference to specific embodiments.

FIG. 4B is a top view of a latch-up structure provided in an embodiment of the present disclosure. FIG. 4C is a sectional view of a latch-up structure provided in an embodiment of the present disclosure.

Before the operation in 401 is performed, the ground pad and power pad are found, the power pad includes pad such as VDD PAD, VDDQ PAD and the like.

Next, as illustrated in FIG. 4C, the operation in 401 is performed. In the chip layout, a first P-type heavily doped region 41 connected to a ground pad and located in a P-well 46 is found, and a first N-type heavily doped region 42 connected to a power pad and located in a deep N-well 47 is found.

In one embodiment, the operation that the first P-type heavily doped region 41 connected to the ground pad and located in the P-well 46 is found, includes the following operation. The first P-type heavily doped region 41 directly or indirectly connected to the ground pad and located in the P-well 46 is found.

The operation that the first N-type heavily doped region 42 connected to the power pad and located in the deep N-well 47 is found, includes the following operation. The first N-type heavily doped region 42 directly or indirectly connected to the power supply pad and is located in the deep N-well 47 is found.

Here, the operation that the first P-type heavily doped region 41 directly connected to the ground pad is found and the operation that the first N-type heavily doped region 42 directly connected to the power pad is found, mean that the ground pad is directly connected to the first P-type heavily doped region 41 and the power pad is directly connected to the first N-type heavily doped region 42 without other devices.

The operation that the first P-type heavily doped region 41 indirectly connected to the ground pad is found and the operation that the first N-type heavily doped region 42 indirectly connected to the power pad is found, mean that the ground pad may be connected to the first P-type heavily doped region 41 and the power pad may be connected to the first N-type heavily doped region 42, respectively, by means of a high current conducting path. Specifically, for example, it may be connected by a resistor having low resistance, a switching device or a diode. More specifically, the ground pad may be connected to the first P-type heavily doped region 41 by means of a forward diode, and the power pad may be connected to the first N-type heavily doped region 42 by means of a backward diode.

Next, the operation in 402 is performed. A second N-type heavily doped region 43 adjacent to the first P-type heavily doped region 41 and located in the P-well 46 is found.

In this embodiment, the second N-type heavily doped region 43 is connected to the ground pad.

The second N-type heavily doped region 43 may be directly or indirectly connected to the ground pad. The indirect connection includes a connection by means of a high current conducting path. Specifically, for example, it may be connected by a resistor having low resistance, a switching device or a diode.

Next, the operation in 403 is performed. A second P-type heavily doped region 44 adjacent to the first N-type heavily doped region 42 and located in the deep N-well 47 is found. the P-well 46 is located in the deep N-well 47, the deep N-well 47 is located in an N-well 48, and the N-well 48 is located in a P-type substrate 45. An area that is formed by the first P-type heavily doped region 41, the first N-type heavily doped region 42, the second P-type heavily doped region 44, the second N-type heavily doped region 43, the P-well 46, the deep N-well 47, the N-well 48 and the P-type substrate 45 is identified as the latch-up structure.

In this embodiment, the second P-type heavily doped region 44 is connected to the power pad.

The second P-type heavily doped region 44 may be directly or indirectly connected to the power pad. The indirect connection includes a connection by means of a high current conducting path. Specifically, for example, it may be connected by a resistor having low resistance, a switching device or a diode.

In one embodiment, the operation that the second N-type heavily doped region 43 adjacent to the first P-type heavily doped region 41 and located in the P-well 46 is found, includes that by taking the first P-type heavily doped region 31 as a center and taking a preset distance as a radius, the second N-type heavily doped region 43 is identified, a distance of which to the first P-type heavily doped region 41 is less than the preset distance; and/or, the operation that the second P-type heavily doped region 44 adjacent to the first N-type heavily doped region 42 and located in the deep N-well 47 is found, includes that by taking the first N-type heavily doped region 42 as a center and taking a preset distance as a radius, the second P-type heavily doped region 44 is identified, a distance of which to the first N-type heavily doped region 42 is less than the preset distance.

In one embodiment, as illustrates in FIG. 4B, there is a first distance L1 between the first N-type heavily doped region 42 and the second P-type heavily doped region 44, a second distance L2 between the second P-type heavily doped region 44 and the second N-type heavily doped region 43, and a third distance L3 between the second N-type heavily doped region 43 and the first P-type heavily doped region 41.

The operation that, by taking the first P-type heavily doped region 41 as a center and taking a preset distance as a radius, the second N-type heavily doped region 43 is identified, a distance of which to the first P-type heavily doped region 41 is less than the preset distance, specifically includes: the third distance is less than the preset distance.

The operation that, by taking the first P-type heavily doped region 42 as a center and taking a preset distance as a radius, the second P-type heavily doped region 44 is identified, a distance of which to the first N-type heavily doped region 42 is less than the preset distance, specifically includes: the first distance is less than the preset distance.

Furthermore, as illustrated in FIG. 4C, a second P-type heavily doped region 44, a deep N-well 47 and a first P-type heavily doped region 41 constitute a first parasitic PNP transistor T1. The second N-type heavily doped region 43, the P-well 46, and the deep N-well 47 constitute a first parasitic NPN transistor T2.

The deep N-well 47 has a first parasitic resistor R_{DNW}, a first end of which is connected to the first N-type heavily doped region 42, and a second end of which is connected to a base electrode of the first parasitic PNP transistor.

The P-well 46 has a second parasitic resistor R_{PW}, a first end of which is connected to the first P-type heavily doped region 41, and a second end of which is connected to a base electrode of the first parasitic NPN transistor T2 and a collector electrode of the first parasitic PNP transistor T1.

The following describes a principle of generating a latch-up effect. Specifically, T1 is a vertical PNP transistor, the base electrode is an N-well, a gain from the base electrode to the collector electrode may reach hundreds of times, T2 is a side NPN transistor, the base electrode is a P-type substrate, the gain from the base electrode to the collector electrode may reach tens of times, R_{DNW} is the parasitic resistor of the deep N-well, and R_{PW} is the parasitic resistor of the P-well.

The above four elements T1, T2, R_{DNW} and R_{PW} constitute a silicon controlled circuit. When there is no external interference and no trigger is caused, the two transistors are in a turned-off state, a collector electrode current is formed by a reverse leakage current of C-B, and a current gain is extremely small, so a latch-up effect will not occur at this time. When a collector electrode current of one of the transistors suddenly increases to a certain value due to external interference, a feedback is sent to the other transistor, so that the two transistors are triggered to be turned on (generally, the PNP is easier to be triggered), and a low-impedance path is formed between the power pad VDD and the ground pad VSS. Then, even if the external interference disappears, because a positive feedback is formed between the two triodes, there will still be a leakage current between the power pad VDD and the ground pad VSS, that is, a locked state. This results in a latch-up effect.

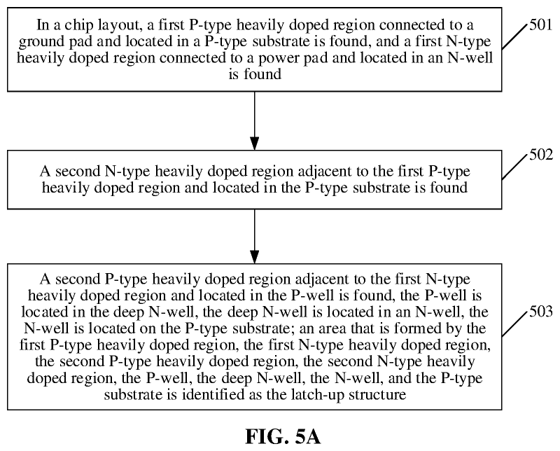

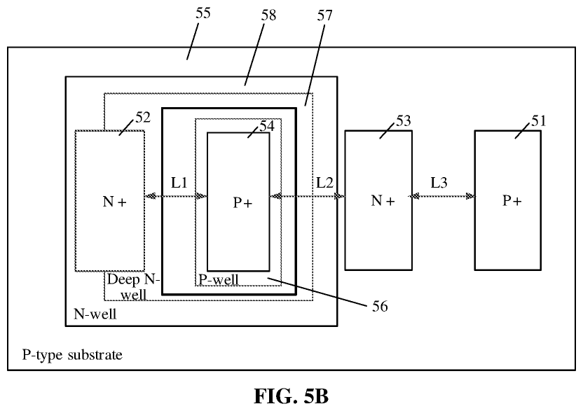

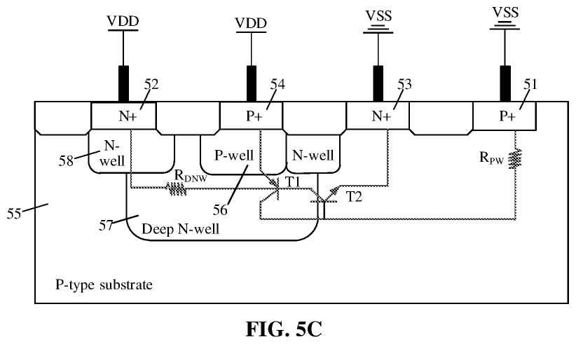

FIG. 5A is a schematic flowchart of a method for identifying a latch-up structure provided in an embodiment of the present disclosure. As illustrated, the method includes the following operations.

In 501, in a chip layout, a first P-type heavily doped region connected to a ground pad and located in a P-type substrate is found, and a first N-type heavily doped region connected to a power pad and located in an N-well is found.

In 502, a second N-type heavily doped region adjacent to the first P-type heavily doped region and located in the P-type substrate is found.

In 503, a second P-type heavily doped region adjacent to the first N-type heavily doped region and located in a P-well is found. The P-well is located in the deep N-well, the deep N-well is located an N-well, the N-well is located in a P-type substrate. An area that is formed by the first P-type heavily doped region, the first N-type heavily doped region, the second P-type heavily doped region, the second N-type heavily doped region, the P-well, the deep N-well, the N-well, and the P-type substrate is identified as the latch-up structure.

The method for identifying a latch-up structure provided in the embodiments of the present disclosure is further described in detail below with reference to specific embodiments.

FIG. 5B is a top view of a latch-up structure provided in an embodiment of the present disclosure. FIG. 5C is a sectional view of a latch-up structure provided in an embodiment of the present disclosure.

Before the operation in 501 is performed, the ground pad and power pad are found, the power pad includes pad such as VDD PAD, VDDQ PAD and the like.

Next, as illustrated in FIG. 5C, the operation in 501 is performed. In a chip layout, a first P-type heavily doped region 51 connected to a ground pad and located in a P-type substrate 55 is found, and a first N-type heavily doped region 52 connected to a power pad and located in an N-well 58 is found.

In one embodiment, the operation that the first P-type heavily doped region 51 connected to the ground pad and located in the P-type substrate 55 is found, includes the following operation. The first P-type heavily doped region 51 directly or indirectly connected to the ground pad and located in the P-type substrate 55 is found.

The operation that the first N-type heavily doped region 52 connected to the power pad and located in the N-well 58 includes the following operation. The first N-type heavily doped region 52 directly or indirectly connected to the power supply pad and located in the N-well 58 is found.

Here, the operation that the first P-type heavily doped region 51 directly connected to the ground pad is found, and the operation that the first N-type heavily doped region 52 directly connected to the power pad, mean that the ground pad is directly connected to the first P-type heavily doped region 51 and the power pad is directly connected to the first N-type heavily doped region 52 without other devices.

The operation that the first P-type heavily doped region 51 indirectly connected to the ground pad is found and the operation that the first N-type heavily doped region 52 indirectly connected to the power pad is found, mean that the ground pad may be connected to the first P-type heavily doped region 51 and the power pad may be connected to the first N-type heavily doped region 52, respectively, by means of a high current conducting path. Specifically, for example, it may be connected by a resistor having low resistance, a switching device or a diode. More specifically, the ground pad may be connected to the first P-type heavily doped region 51 by means of a forward diode, and the power pad may be connected to the first N-type heavily doped region 52 by means of a backward diode.

Next, the operation in 502 is performed. A second N-type heavily doped region 53 adjacent to the first P-type heavily doped region 51 and located in the P-type substrate 55 is found.

In this embodiment, the second N-type heavily doped region 53 is connected to the ground pad.

The second N-type heavily doped region 53 may be directly or indirectly connected to the ground pad. The indirect connection includes a connection by means of a high current conducting path. Specifically, for example, it may be connected by a resistor having low resistance, a switching device or a diode.

Next, the operation in 503 is performed. A second P-type heavily doped region 54 adjacent to the first N-type heavily doped region 52 and located in a P-well 56 is found. The P-well 56 is located in the deep N-well 57, the deep N-well 57 is located in the N-well 58, and the N-well 58 is located on a P-type substrate 55. An area that is formed by the first P-type heavily doped region 51, the first N-type heavily doped region 52, the second P-type heavily doped region 54, the second N-type heavily doped region 53, the P-well 56, the deep N-well 57, the N-well 58 and the P-type substrate 55 is identified as the latch-up structure.

In this embodiment, the second P-type heavily doped region 54 is connected to the power pad.

The second P-type heavily doped region 54 may be directly or indirectly connected to the power pad. The indirect connection includes a connection by means of a high current conducting path. Specifically, for example, it may be connected by a resistor having low resistance, a switching device or a diode.

In one embodiment, the operation that the second N-type heavily doped region 53 adjacent to the first P-type heavily doped region 51 and located in the P-type substrate 55 includes that by taking the first P-type heavily doped region 51 as a center and taking a preset distance as a radius, the second N-type heavily doped region 53 is identified, a distance of which to the first P-type heavily doped region 51 is less than the preset distance, and/or, the operation that the second P-type heavily doped region 54 adjacent to the first N-type heavily doped region 52 and located in a P-well 56 is found, includes that by taking the first N-type heavily doped region 52 as a center and taking a preset distance as a radius, the second P-type heavily doped region 54 is identified, a distance of which to the first N-type heavily doped region 52 is less than the preset distance.

In one embodiment, as illustrates in FIG. 5B, there is a first distance L1 between the first N-type heavily doped region 52 and the second P-type heavily doped region 54, a second distance L2 between the second P-type heavily doped region 54 and the second N-type heavily doped region 53, and a third distance L3 between the second N-type heavily doped region 53 and the first P-type heavily doped region 51.

The operation that, by taking the first P-type heavily doped region 51 as a center and taking a preset distance as a radius, the second N-type heavily doped region 53 is identified, a distance of which to the first P-type heavily doped region 51 is less than the preset distance, specifically includes: the third distance is less than the preset distance.

The operation that, by taking the first N-type heavily doped region 52 as a center and taking a preset distance as a radius, the second P-type heavily doped region 54 with a distance to the first N-type heavily doped region 52 less than the preset distance is identified, specifically includes: the first distance is less than the preset distance.

Furthermore, as illustrated in FIG. 5C, the P-well 56, the deep N-well 57 and the P-type substrate 55 constitute a first parasitic PNP transistor T1. The deep N-well 57, the P-type substrate 55 and the second N-type heavily doped region 53 constitute a first parasitic NPN transistor T2.

The deep N-well 57 has a first parasitic resistor R_{DNW}, a first end of which is connected to the first N-type heavily doped region 52, and a second end of which is connected to a base electrode of the first parasitic PNP transistor T1.

The P-type substrate 55 has a second parasitic resistor R_{PW}, a first end of which is connected to the first P-type heavily doped region 51, and a second end of which is connected to the base electrode of the first parasitic NPN transistor T2 and a collector electrode of the first parasitic PNP transistor T1.

The following describes a principle of generating a latch-up effect. Specifically, T1 is a vertical PNP transistor, the base electrode is an N-well, a gain from the base electrode to the collector electrode may reach hundreds of times, T2 is a side NPN transistor, the base electrode is a P-type substrate, a gain from the base electrode to the collector electrode may reach tens of times, R_{DNW} is the parasitic resistor of the deep N-well, and R_{PW} is the parasitic resistor of the P-type substrate.

The above four elements T1, T2, R_{DNW} and R_{PW} constitute a silicon controlled circuit. When there is no external interference and no trigger is caused, the two transistors are in a turned-off state, a collector electrode current is formed by a reverse leakage current of C-B, and a current gain is extremely small, so the latch-up effect will not occur at this time. When a collector electrode current of one of the transistors suddenly increases to a certain value due to external interference, a feedback is sent to the other transistor, so that the two transistors are triggered to be turned on (generally, the PNP is easier to be triggered), and a low-impedance path is formed between the power pad VDD and the ground pad VSS. Then, even if the external interference disappears, because a positive feedback is formed between the two triodes, there will still be a leakage current between the power pad VDD and the ground pad VSS, that is, a locked state. This results in a latch-up effect.

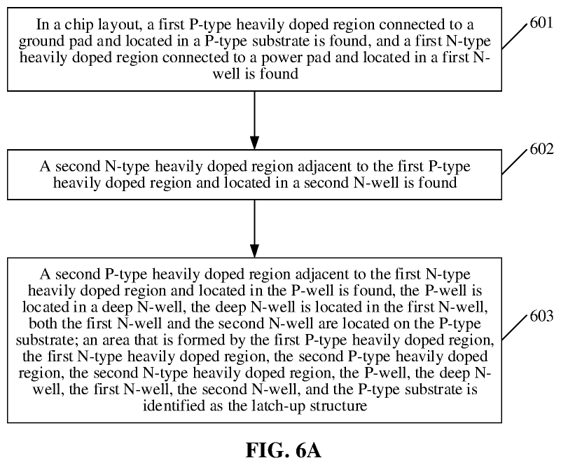

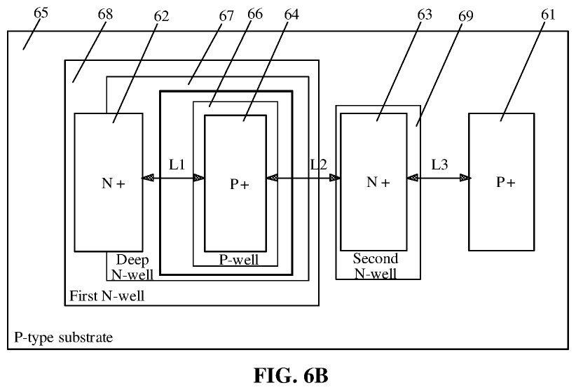

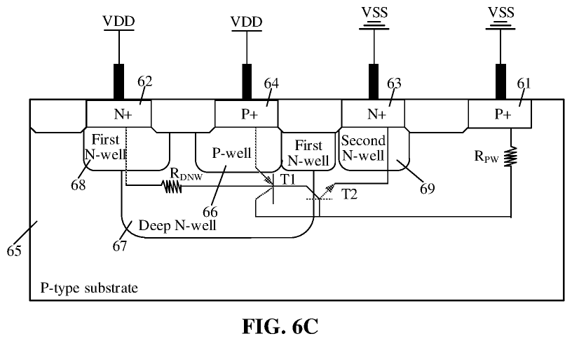

FIG. 6A is a schematic flowchart of a method for identifying a latch-up structure provided in an embodiment of the present disclosure. As illustrated, the method includes the following operations.

In 601, in a chip layout, a first P-type heavily doped region connected to a ground pad and located in a P-type substrate is found, and a first N-type heavily doped region connected to a power pad and located in a first N-well is found.

In 602, a second N-type heavily doped region adjacent to the first P-type heavily doped region and located in a second N-well is found.

In 603, a second P-type heavily doped region adjacent to the first N-type heavily doped region and located in a P-well is found. The P-well is located in a deep N-well, the deep N-well is located in the first N-well, and both the first N-well and the second N-well are located in the P-type substrate. An area that is formed by the first P-type heavily doped region, the first N-type heavily doped region, the second P-type heavily doped region, the second N-type heavily doped region, the P-well, the deep N-well, the first N-well, the second N-well and the P-type substrate is identified as the latch-up structure.

The method for identifying a latch-up structure according to the embodiments of the present disclosure is further described in detail below with reference to specific embodiments.

FIG. 6B is a top view of a latch-up structure provided in an embodiment of the present disclosure. FIG. 6C is a sectional view of a latch-up structure provided in an embodiment of the present disclosure.

Before the operation in 601 is performed, a ground pad and a power pad are found, the power pad includes pad such as VDD PAD, VDDQ PAD and the like.

Next, as illustrated in FIG. 6C, the operation in 601 is performed. In the chip layout, a first P-type heavily doped region 61 connected to a ground pad and located in a P-type substrate 65 is found, and a first N-type heavily doped region 62 connected to the power pad and located in a first N-well 68 is found.

In one embodiment, the operation that the first P-type heavily doped region 61 connected to the ground pad and located in the P-type substrate 65 is found, includes the following operation. The first P-type heavily doped region 61 directly or indirectly connected to the ground pad and located in the P-type substrate 65 is found.

The operation that the first N-type heavily doped region 62 connected to the power pad and located in a first N-well 68 is found, includes the following operation. The first N-type heavily doped region 62 directly or indirectly connected to the power supply pad and located in the first N-well 68 is found.

Here, the operation that the first P-type heavily doped region 61 directly connected to the ground pad is found and the operation that the first N-type heavily doped region 62 directly connected to the power pad is found, mean that the ground pad is directly connected to the first P-type heavily doped region 61 and the power pad is directly connected to the first N-type heavily doped region 62 without other devices.

The operation that the first P-type heavily doped region 61 indirectly connected to the ground pad is found and the operation that the first N-type heavily doped region 62 indirectly connected to the power pad is found, mean that the ground pad may be connected to the first P-type heavily doped region 61 and the power pad may be connected to the first N-type heavily doped region 62, respectively, by means of a high current conducting path. Specifically, for example, it may be connected by a resistor having low resistance, a switching device or a diode. More specifically, the ground pad may be connected to the first P-type heavily doped region 61 by means of a forward diode, and the power pad may be connected to the first N-type heavily doped region 62 by means of a backward diode.

Next, the operation in 602 is performed. A second N-type heavily doped region 63 adjacent to the first P-type heavily doped region 61 and located in the second N-well 69 is found.

In this embodiment, the second N-type heavily doped region 63 is connected to the ground pad.

The second N-type heavily doped region 63 may be directly or indirectly connected to the ground pad. The indirect connection includes a connection by means of a high current conducting path. Specifically, for example, it may be connected by a resistor having low resistance, a switching device or a diode.

Next, the operation in 603 is performed. A second P-type heavily doped region 64 adjacent to the first N-type heavily doped region 62 and located in a P-well 66 is found. The P-well 66 is located in the deep N-well 67, the deep N-well 67 is located in the first N-well 68, and both the first N-well 68 and the second N-well 69 are located in the P-type substrate 65. An area that is formed by the first P-type heavily doped region 61, the first N-type heavily doped region 62, the second P-type heavily doped region 64, the second N-type heavily doped region 63, the P-well 66, the deep N-well 67, the first N-well 68, the second N-well 69 and the P-type substrate 65 is identified as the latch-up structure.

In this embodiment, the second P-type heavily doped region 64 is connected to the power pad.

The second P-type heavily doped region 64 may be directly or indirectly connected to the power pad. The indirect connection includes a connection by means of a high current conducting path. Specifically, for example, it may be connected by a resistor having low resistance, a switching device or a diode.

In one embodiment, the operation that the second N-type heavily doped region 63 adjacent to the first P-type heavily doped region 61 and located in a second N-well 69 is found, includes that by taking the first P-type heavily doped region 61 as a center and taking a preset distance as a radius, the second N-type heavily doped region 63 is identified, a distance of which to the first P-type heavily doped region 61 is less than the preset distance; and/or, the operation that the second P-type heavily doped region 64 adjacent to the first N-type heavily doped region 62 and located in the P-well 66 is found, includes that by taking the first N-type heavily doped region 22 as a center and taking a preset distance as a radius, the second P-type heavily doped region 64 is identified, a distance of which to the first N-type heavily doped region 62 is less than the preset distance.

In one embodiment, as illustrates in FIG. 6B, there is a first distance L1 between the first N-type heavily doped region 62 and the second P-type heavily doped region 64, a second distance L2 between the second P-type heavily doped region 64 and the second N-type heavily doped region 63, and a third distance L3 between the second N-type heavily doped region 63 and the first P-type heavily doped region 61.

The operation that, by taking the first P-type heavily doped region 61 as a center and taking a preset distance as a radius, the second N-type heavily doped region 63 is identified, a distance of which to the first P-type heavily doped region 61 is less than the preset distance, specifically includes: the first distance is less than the preset distance.

The operation that, by taking the first N-type heavily doped region 62 as a center and taking a preset distance as a radius, the second P-type heavily doped region 64 is identified, a distance of which to the first N-type heavily doped region 62 is less than the preset distance, specifically includes: the first distance is less than the preset distance.

Furthermore, as illustrated in FIG. 6C, the P-well 66, the deep N-well 67 and the P-type substrate 65 constitute a first parasitic PNP transistor T1. The deep N-well 67, the P-type substrate 65 and the second N-well 69 constitute a first parasitic NPN transistor T2.

The deep N-well 67 has a first parasitic resistor R_{DNW}, a first end of which is connected to the first N-type heavily doped region 62, and a second end of which is connected to a base electrode of the first parasitic PNP transistor.

The P-type substrate 65 has a second parasitic resistor R_{PW}, a first end of which is connected to the first P-type heavily doped region 61, and a second end of which is connected to a base electrode of the first parasitic NPN transistor T2 and the collector electrode of the first parasitic PNP transistor T1.

The following describes a principle of generating a latch-up effect.

Specifically, T1 is a vertical PNP transistor, the base electrode is an N-well, a gain from the base electrode to the collector electrode may reach hundreds times, T2 is a side NPN transistor, the base electrode is a P-type substrate, a gain from the base electrode to the collector electrode may reach tens of times, R_{DNW} is a parasitic resistor of the deep N-well, and R_{PW} is a parasitic resistor of the P-type substrate.

The above four elements T1, T2, R_{DNW} and R_{PW} constitute a silicon controlled circuit. When there is no external interference and no trigger is caused, the two transistors are in a turned-off state, a collector electrode current is formed by a reverse leakage current of C-B, and a current gain is extremely small, so the latch-up effect will not occur at this time. When a collector electrode current of one of the transistors suddenly increases to a certain value due to external interference, a feedback is sent to the other transistor, so that the two transistors are turned on due to triggering (generally, the PNP is easier to be triggered), and a low-impedance path is formed between the power pad VDD and the ground pad VSS. Then, even if the external interference disappears, because a positive feedback is formed between the two triodes, there will still be a leakage current between the power pad VDD and the ground pad VSS, that is, a locked state. This results in a latch-up effect.

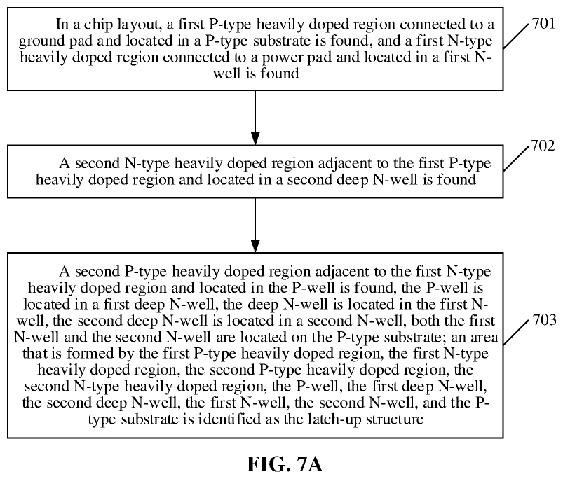

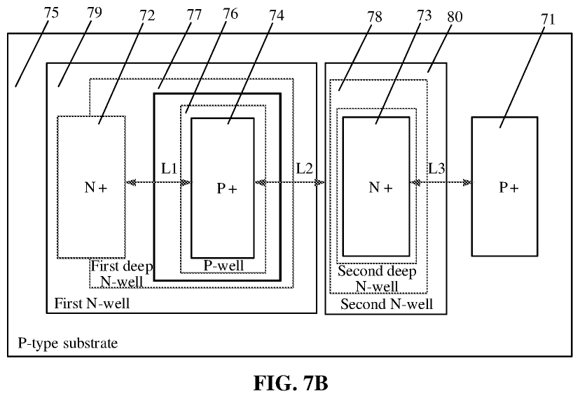

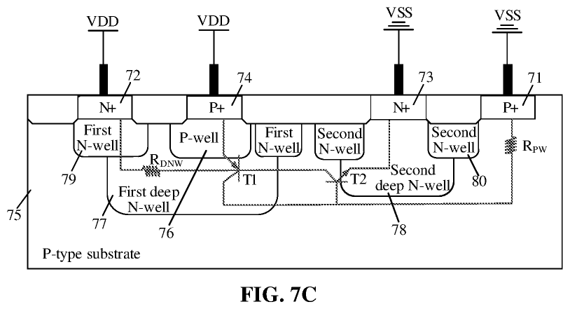

FIG. 7A is a schematic flowchart of a method for identifying a latch-up structure provided in an embodiment of the present disclosure. As illustrated, the method includes the following operations.

In 701, in a chip layout, a first P-type heavily doped region connected to a ground pad and located in a P-type substrate is found, and a first N-type heavily doped region connected to a power pad and located in a first N-well is found.

In 702, a second N-type heavily doped region adjacent to the first P-type heavily doped region and located in a second deep N-well is found.

In 703, a second P-type heavily doped region adjacent to the first N-type heavily doped region and located in a P-well is found. The P-well is located in a first deep N-well, the first deep N-well is located the first N-well, the second deep N-well is located in a second N-well, and both the first N-well and the second N-well are located in a P-type substrate. An area that is formed by the first P-type heavily doped region, the first N-type heavily doped region, the second P-type heavily doped region, the second N-type heavily doped region, the P-well, the first deep N-well, the second deep N-well, the first N-well, the second N-well and the P-type substrate is identified as the latch-up structure.

The method for identifying a latch-up structure provided in the embodiments of the present disclosure is further described in detail below with reference to specific embodiments.

FIG. 7B is a top view of a latch-up structure provided in an embodiment of the present disclosure. FIG. 7C is a sectional view of a latch-up structure provided in an embodiment of the present disclosure.

Before the operation in 701 is performed, the ground pad and power pad are found, the power pad includes pad such as VDD PAD, VDDQ PAD and the like.

Next, as illustrated in FIG. 7C, the operation in 701 is performed. In the chip layout, a first P-type heavily doped region 71 connected to a ground pad and located in a P-type substrate 75 is found, and the first N-type heavily doped region 72 connected to the power pad and located in a first N-well 79 is found.

In one embodiment, the operation that the first P-type heavily doped region 71 connected to the ground pad and located in the P-type substrate 75 is found, includes the following operation. The first P-type heavily doped region 71 directly or indirectly connected to the ground pad and located in the P-type substrate 75 is found.

The operation that the first N-type heavily doped region 72 connected to the power pad and located in a first N-well 79 is found, includes the following operation. The first N-type heavily doped region 72 directly or indirectly connected to the power supply pad and located in the first N-well 79 is found.

Here, the operation that the first P-type heavily doped region 71 directly connected to the ground pad is found and the operation that the first N-type heavily doped region 72 directly connected to the power pad is found, mean that the ground pad is directly connected to the first P-type heavily doped region 71 and the power pad is directly connected to the first N-type heavily doped region 72 without other devices.

The operation that the first P-type heavily doped region 71 indirectly connected to the ground pad is found and the operation that the first N-type heavily doped region 72 indirectly connected to the power pad, mean that the ground pad may be connected to the first P-type heavily doped region 71 and the power pad may be connected to the first N-type heavily doped region 72, respectively, by means of a high current conducting path. Specifically, for example, it may be connected by a resistor having low resistance, a switching device or a diode. More specifically, the ground pad may be connected to the first P-type heavily doped region 71 by means of a forward diode, and the power pad may be connected to the first N-type heavily doped region 72 by means of a backward diode.

Next, the operation in 702 is performed. A second N-type heavily doped region 73 adjacent to the first P-type heavily doped region 71 and located in the second deep N-well 78 is found.

In this embodiment, the second N-type heavily doped region 73 is connected to the ground pad.

The second N-type heavily doped region 73 may be directly or indirectly connected to the ground pad. The indirect connection includes a connection by means of a high current conducting path. Specifically, for example, it may be connected by a resistor having low resistance, a switching device or a diode.

Next, the operation in 703 is performed. A second P-type heavily doped region 74 adjacent to the first N-type heavily doped region 72 and located in a P-well 76, the P-well 76 is located in a first deep N-well 77, the first deep N-well 77 is located in the first N-well 79, the second deep N-well 78 is located in the second N-well 80, both the first N-well 79 and the second N-well 80 are located in the P-type substrate 75, An area that is formed by the first P-type heavily doped region 71, the first N-type heavily doped region 72, the second P-type heavily doped region 74, the second N-type heavily doped region 73, the P-well 76, the first deep N-well 77, the second deep N-well 78, the first N-well 79, the second N-well 80 and the P-type substrate 75 is identified as the latch-up structure.

In this embodiment, the second P-type heavily doped region 74 is connected to the power pad.

The second P-type heavily doped region 74 may be directly or indirectly connected to the power pad. The indirect connection includes a connection by means of a high current conducting path. Specifically, for example, it may be connected by a resistor having low resistance, a switching device or a diode.

In one embodiment, the operation that the second N-type heavily doped region 73 adjacent to the first P-type heavily doped region 71 and located in a second deep N-well 78 is found, includes that by taking the first P-type heavily doped region 71 as a center and taking a preset distance as a radius, the second N-type heavily doped region 73 is identified, a distance of which to the first P-type heavily doped region 71 is less than the preset distance; and/or, the operation that the second P-type heavily doped region 74 adjacent to the first N-type heavily doped region 72 and located in a P-well 76 is found, includes that by taking the first N-type heavily doped region 72 as a center and taking a preset distance as a radius, the second P-type heavily doped region 74 is identified, a distance of which to the first N-type heavily doped region 72 is less than the preset distance.

In one embodiment, as illustrates in FIG. 7B, there is a first distance L1 between the first N-type heavily doped region 72 and the second P-type heavily doped region 74, a second distance L2 between the second P-type heavily doped region 74 and the second N-type heavily doped region 73, and a third distance L3 between the second N-type heavily doped region 73 and the first P-type heavily doped region 71.

The operation that, by taking the first P-type heavily doped region 71 as a center and taking a preset distance as a radius, the second N-type heavily doped region 73 is identified, a distance of which to the first P-type heavily doped region 71 is less than the preset distance, specifically includes: the first distance is less than the preset distance.

The operation that, by taking the first N-type heavily doped region 72 as a center and taking a preset distance as a radius, the second P-type heavily doped region 74 is identified, a distance of which to the first N-type heavily doped region 72 is less than the preset distance, specifically includes: the first distance is less than the preset distance.

Furthermore, as illustrated in FIG. 7C, the P-well 76, the first deep N-well 77 and the P-type substrate 75 constitute a first parasitic PNP transistor T1. The first deep N-well 77, the P-type substrate 75 and the second deep N-well 78 constitute a first parasitic NPN transistor T2.

The first deep N-well 77 has a first parasitic resistor R_{DNW}, a first end of which is connected to the first N-type heavily doped region 72, and a second end of which is connected to a base electrode of the first parasitic PNP transistor T1.

The P-type substrate 75 has a second parasitic resistor R_{PW}, a first end of which is connected to the first P-type heavily doped region 71, and a second end of which is connected to the base electrode of the first parasitic NPN transistor T2 and a collector electrode of the first parasitic PNP transistor T1.

The following describes a principle of generating a latch-up effect. Specifically, T1 is a vertical PNP transistor, the base electrode is an N-well, a gain from the base electrode to a collector electrode may reach hundreds of times, T2 is a side NPN transistor, the base electrode is a P-type substrate, a gain from the base electrode to the collector electrode may reach tens of times, R_{DNW} is a parasitic resistor of the first deep N-well, and R_{PW} is a parasitic resistor of the P-type substrate.

The above four elements T1, T2, R_{DNW} and R_{PW} constitute a silicon controlled circuit. When there is no external interference and no triggering, the two transistors are in a turned-off state, a collector electrode current is formed by a reverse leakage current of C-B, and a current gain is extremely small, so the latch-up effect will not occur at this time. When a collector electrode current of one of the transistors suddenly increases to a certain value due to external interference, a feedback is sent to the other transistor, so that the two transistors are triggered to be turned on (generally, the PNP is easier to be triggered), and a low-impedance path is formed between the power pad VDD and the ground pad VSS. Then, even if the external interference disappears, because a positive feedback is formed between the two triodes, there will still be a leakage current between the power pad VDD and the ground pad VSS, that is, the locked state. This results in a latch-up effect.

The foregoing descriptions are merely preferred embodiments of the present disclosure, and are not intended to limit the scope of protection of the present disclosure. Any modification, equivalent replacement, improvement and the like made within the spirit and principles of the present disclosure shall be included within the scope of protection of the present disclosure.

### INDUSTRIAL APPLICABILITY

In the embodiments of the present disclosure, by finding the first P-type heavily doped region connected to the ground pad, the first N-type heavily doped region connected to the power pad, and finding the second N-type heavily doped region and the second P-type heavily doped region respectively by means of the first P-type heavily doped region and the first N-type heavily doped region, the latch-up structure connected to the ground pad and the power pad is identified, thereby corresponding design rules may be used to inspect whether it is safe to ensure the reliability of the device.

1. A method for identifying a latch-up structure, the method comprising:
in a chip layout, finding a first P-type heavily doped region connected to a ground pad and located in a P-type substrate, and finding a first N-type heavily doped region connected to a power pad and located in an N-well;
finding a second N-type heavily doped region adjacent to the first P-type heavily doped region and located in the P-type substrate;
finding a second P-type heavily doped region adjacent to the first N-type heavily doped region and located in the N-well, wherein the N-well is located on the P-type substrate; and
identifying, as the latch-up structure, an area that is formed by the first P-type heavily doped region, the first N-type heavily doped region, the second P-type heavily doped region, the second N-type heavily doped region, the N-well, and the P-type substrate.

2. The method of claim 1, wherein at least one of the following applies:
finding the second N-type heavily doped region adjacent to the first P-type heavily doped region and located in the P-type substrate comprises:
identifying, by taking the first P-type heavily doped region as a center and taking a preset distance as a radius, the second N-type heavily doped region, a distance of which to the first P-type heavily doped region is less than the preset distance;
or,
finding the second P-type heavily doped region adjacent to the first N-type heavily doped region and located in the N-well comprises:
identifying, by taking the first N-type heavily doped region as a center and taking a preset distance as a radius, the second P-type heavily doped region, a distance of which to the first N-type heavily doped region is less than the preset distance.

3. The method of claim 1, wherein,
finding the first P-type heavily doped region connected to the ground pad and located in the P-type substrate comprises:
finding the first P-type heavily doped region directly or indirectly connected to the ground pad and located in the P-type substrate; and
finding the first N-type heavily doped region connected to the power pad and located in the N-well comprises:
finding the first N-type heavily doped region directly or indirectly connected to the power pad and located in the N-well.

4. A method for identifying a latch-up structure, the method comprising:
in a chip layout, finding a first P-type heavily doped region connected to a ground pad and located in a P-type substrate, and finding a first N-type heavily doped region connected to a power pad and located in a second N-well;
finding a second N-type heavily doped region adjacent to the first P-type heavily doped region and located in a first N-well;
finding a second P-type heavily doped region adjacent to the first N-type heavily doped region and located in the second N-well, wherein both the first N-well and the second N-well are located on the P-type substrate; and
identifying, as the latch-up structure, an area that is formed by the first P-type heavily doped region, the first N-type heavily doped region, the second P-type heavily doped region, the second N-type heavily doped region, the first N-well, the second N-well, and the P-type substrate.

5. The method of to claim 4, wherein at least one of the following applies:
finding the second N-type heavily doped region adjacent to the first P-type heavily doped region and located in the first N-well comprises:
identifying, by taking the first P-type heavily doped region as a center and taking a preset distance as a radius, the second N-type heavily doped region, a distance of which to the first P-type heavily doped region is less than the preset distance;
or,
finding the second P-type heavily doped region adjacent to the first N-type heavily doped region and located in the second N-well comprises:
identifying, by taking the first N-type heavily doped region as a center and taking a preset distance as a radius, the second P-type heavily doped region, a distance of which to the first N-type heavily doped region is less than the preset distance.

6. The method of claim 4, wherein,
finding the first P-type heavily doped region connected to the ground pad and located in the P-type substrate comprises:
finding the first P-type heavily doped region directly or indirectly connected to the ground pad and located in the P-type substrate; and
finding the first N-type heavily doped region connected to the power pad and located in the second N-well comprises:
finding the first N-type heavily doped region directly or indirectly connected to the power pad and located in the second N-well.

7. A method for identifying a latch-up structure, the method comprising:
in a chip layout, finding a first P-type heavily doped region connected to a ground pad and located in a P-type substrate, and finding a first N-type heavily doped region connected to a power pad and located in a second N-well;
finding a second N-type heavily doped region adjacent to the first P-type heavily doped region and located in a deep N-well;
finding a second P-type heavily doped region adjacent to the first N-type heavily doped region and located in the second N-well, wherein the deep N-well is located in a first N-well, both the first N-well and the second N-well are located on the P-type substrate; and
identifying, as the latch-up structure, an area that is formed by the first P-type heavily doped region, the first N-type heavily doped region, the second P-type heavily doped region, the second N-type heavily doped region, the deep N-well, the first N-well, the second N-well, and the P-type substrate.

8. The method of claim 7, wherein at least one of the following applies:
finding the second N-type heavily doped region adjacent to the first P-type heavily doped region and located in the deep N-well comprises:
identifying, by taking the first P-type heavily doped region as a center and taking a preset distance as a radius, the second N-type heavily doped region, a distance of which to the first P-type heavily doped region is less than the preset distance;
or,
finding the second P-type heavily doped region adjacent to the first N-type heavily doped region and located in the second N-well comprises:
identifying, by taking the first N-type heavily doped region as a center and taking a preset distance as a radius, the second P-type heavily doped region, a distance of which to the first N-type heavily doped region is less than the preset distance.

9. The method of claim 7, wherein,
finding the first P-type heavily doped region connected to the ground pad and located in the P-type substrate comprises:
finding the first P-type heavily doped region directly or indirectly connected to the ground pad and located in the P-type substrate; and
finding the first N-type heavily doped region connected to the power pad and located in the second N-well comprises:
finding the first N-type heavily doped region directly or indirectly connected to the power pad and located in the second N-well.
